(19) United States
(12) Patent Application Publication
(10) Pub. No.: US 2025/0066167 A1
(43) Pub. Date: Feb. 27, 2025

(54) ARTICLE TRANSPORT FACILITY

(71) Applicant: Daifuku Co., Ltd., Osaka (JP)

(72) Inventor: Tomotaka KINUGAWA, Shiga (JP)

(21) Appl. No.: 18/808,780

(22) Filed: Aug. 19, 2024

(30) Foreign Application Priority Data
Aug. 23, 2023 (JP) 2023-135492

(51) Int. Cl. B66C 19/00; B66C 13/18; H01L 21/677

(52) U.S. Cl. CPC B66C 19/00; B66C 13/18; H01L 21/67712; H01L 21/67727

(57) ABSTRACT

An article transport facility includes a transport vehicle, a first level rail, a second level rail, and an inter-level transport apparatus. The inter-level transport apparatus includes a first elevation rail, a second elevation rail, and an elevation mechanism. The first level rail includes a first rail portion connected to the first elevation rail present at a first stop position, and a second rail portion connected to the second elevation rail present at the first stop position. The second level rail includes a third rail portion connected to the first elevation rail present at a second stop position, and a fourth rail portion connected to the second elevation rail present at the second stop position.

### CROSS-REFERENCE TO RELATED APPLICATIONS

This application is based on and claims priority from Japanese Patent Application No. 2023-135492, filed on Aug. 23, 2023, with the Japan Patent Office, the disclosure of which is incorporated herein in its entirety by reference.

### TECHNICAL FIELD

The present disclosure relates to an article transport facility.

### BACKGROUND

In a building having multiple levels (floors), article transport facilities are used to transport articles between the levels. Japanese Patent Laid-Open Publication No. 06-171888 discloses an example of an article transport facility. The article transport facility (material transport apparatus) of Japanese Patent Laid-Open Publication No. 06-171888 includes a plurality of transport vehicles (traveling trolleys 8), and an inter-level transport apparatus (a traverse winding device 5 and an elevation rail 7) that transports the transport vehicles in a vertical direction between a first level (first floor) and a second level (second floor).

### SUMMARY

According to an aspect of the present disclosure, an article transport facility includes: a plurality of transport vehicles that transport articles inside a building with a plurality of levels; a first level rail disposed in a first level, which is one of the plurality of levels, and allowing the plurality of transport vehicles to travel thereon; a second level rail disposed in a second level, which is one of the plurality of levels and different from the first level, and allowing the plurality of transport vehicles to travel thereon; and an inter-level transport apparatus that transports the plurality of transport vehicles in a vertical direction over the first level and the second level. The inter-level transport apparatus includes a first elevation rail, on which the plurality of transport vehicles travel, a second elevation rail, on which the plurality of transport vehicles travel, the second elevation rail being provided in parallel with the first elevation rail, and an elevation mechanism configured to move the first elevation rail and the second elevation rail in the vertical direction while maintaining a positional relationship between the first elevation rail and the second elevation rail, the elevation mechanism stops the first elevation rail and the second elevation rail at a predetermined first stop position in the first level and a predetermined second stop position in the second level, a direction along each of the first level rail and the second level rail is a traveling direction, one side of the traveling direction is a first side of the traveling direction, and an opposite side of the traveling direction is a second side of the traveling direction, the first level rail includes a first rail portion that is connected to the first elevation rail present at the first stop position from the first side of the traveling direction, and a second rail portion that is connected to the second elevation rail present at the first stop position from the first side of the traveling direction, and the second level rail includes a third rail portion that is connected to the first elevation rail present at the second stop position from the first or second side of the traveling direction, and a fourth rail portion that is connected to the second elevation rail present at the second stop position from the first or second side of the traveling direction.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a perspective view illustrating an article transport facility.

FIG. 2 is a front view of a lower-level rail and a transport vehicle.

FIG. 3 is a schematic view illustrating an inter-level transport apparatus and surroundings thereof.

FIG. 4 is a schematic view illustrating an example of article transport by a transport vehicle.

FIG. 5 is a schematic view illustrating an example of article transport by a transport vehicle.

FIG. 6 is a schematic view illustrating an example of article transport by a transport vehicle.

FIG. 7 is a schematic view illustrating an example of article transport by a transport vehicle.

FIG. 8 is a schematic view illustrating an example of article transport by a transport vehicle.

FIG. 9 is a schematic view illustrating an example of article transport by a transport vehicle.

FIG. 10 is a schematic view illustrating an example of article transport by a transport vehicle.

FIG. 11 is a schematic view illustrating an example of article transport by a transport vehicle.

FIG. 12 is a flowchart of a process for a transport vehicle passing in the vicinity of the inter-level transport apparatus.

FIG. 13 is a schematic view illustrating another aspect of the inter-level transport apparatus and surroundings thereof.

### DETAILED DESCRIPTION

In the following detailed description, reference is made to the accompanying drawings which form a part hereof. The illustrative embodiments described in the detailed description, drawings, and claims are not meant to be limiting. Other embodiments may be utilized, and other changes may be made without departing from the spirit or scope of the subject matter presented herein.

In Japanese Patent Laid-Open Publication No. 06-171888, since the article transport facility is configured to transport vehicles one by one between the levels (floors) of a building, the efficiency in transporting the transport vehicles between the levels is poor.

Accordingly, it is necessary to implement an article transport facility with the improved efficiency in transporting articles between multiple levels.

An article transport facility according to the present disclosure includes: a plurality of transport vehicles that transport articles inside a building with a plurality of levels; a first level rail disposed in a first level, which is one of the plurality of levels, and allowing the plurality of transport vehicles to travel thereon; a second level rail disposed in a second level, which is one of the plurality of levels and different from the first level, and allowing the plurality of transport vehicles to travel thereon; and an inter-level transport apparatus that transports the plurality of transport vehicles in a vertical direction over the first level and the second level. The inter-level transport apparatus includes a first elevation rail, on which the plurality of transport vehicles travel, a second elevation rail, on which the plurality of transport vehicles travel, the second elevation rail being provided in parallel with the first elevation rail, and an elevation mechanism configured to move the first elevation rail and the second elevation rail in the vertical direction while maintaining a positional relationship between the first elevation rail and the second elevation rail, the elevation mechanism stops the first elevation rail and the second elevation rail at a predetermined first stop position in the first level and a predetermined second stop position in the second level, a direction along each of the first level rail and the second level rail is a traveling direction, one side of the traveling direction is a first side of the traveling direction, and an opposite side of the traveling direction is a second side of the traveling direction, the first level rail includes a first rail portion that is connected to the first elevation rail present at the first stop position from the first side of the traveling direction, and a second rail portion that is connected to the second elevation rail present at the first stop position from the first side of the traveling direction, and the second level rail includes a third rail portion that is connected to the first elevation rail present at the second stop position from the first or second side of the traveling direction, and a fourth rail portion that is connected to the second elevation rail present at the second stop position from the first or second side of the traveling direction.

According to this configuration, two or more transport vehicles may be simultaneously transported from one level to another level. Thus, as compared to a configuration in which transport vehicles are transported one by one between levels, the efficiency in transporting the transport vehicles between the levels may be improved. Therefore, it is possible to provide an article transport facility with the improved efficiency in transporting articles between multiple levels.

Other features and advantages of the technology according to the present disclosure may clearly be understood from the illustrative and non-limiting descriptions of embodiments that are provided herein below with reference to the drawings.

Hereinafter, embodiments of the article transport facility are described with reference to the drawings.

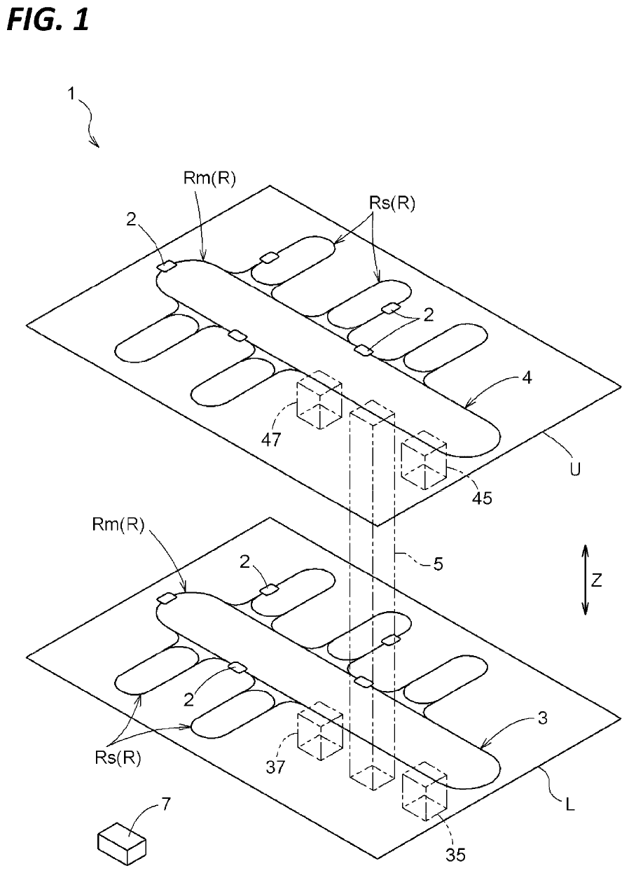

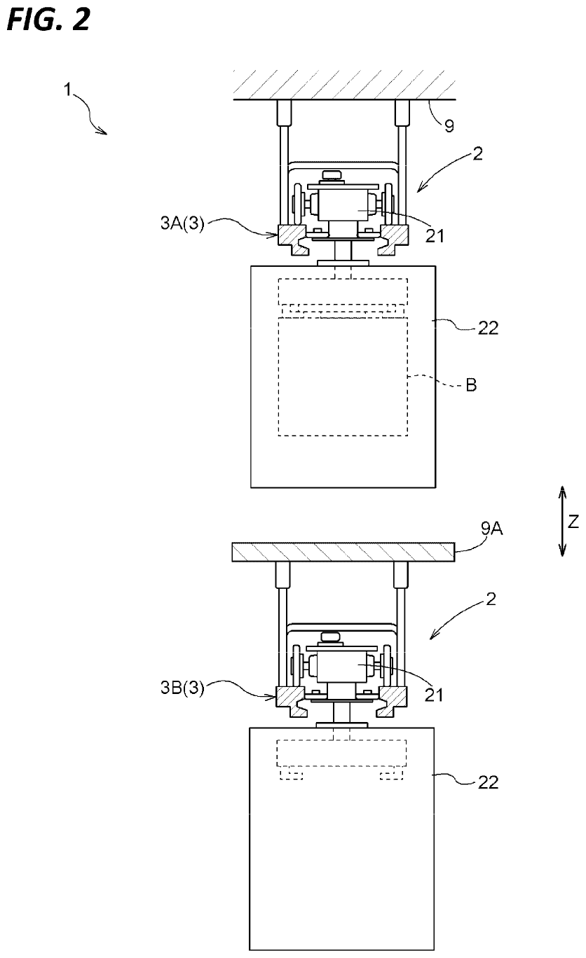

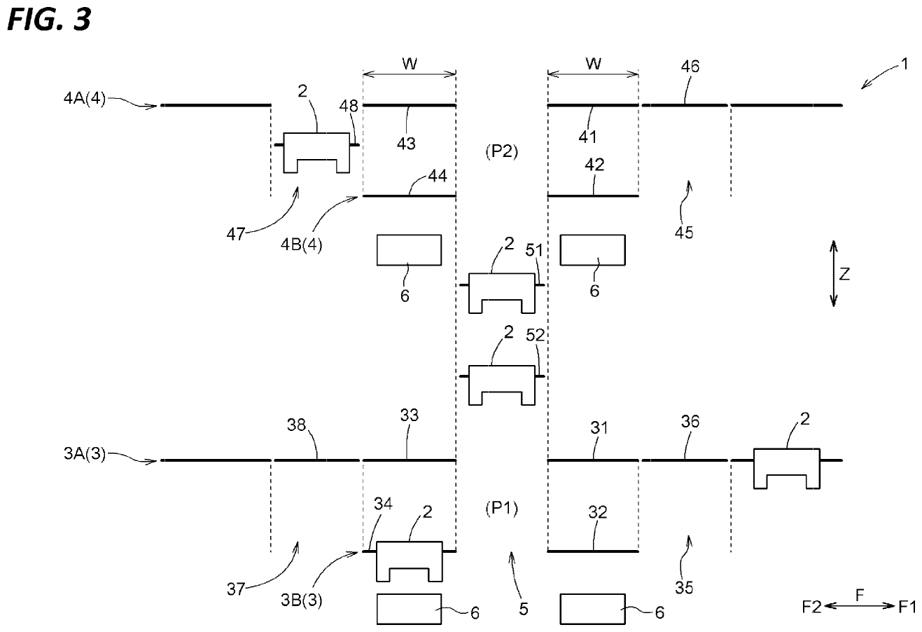

As illustrated in FIG. 1, an article transport facility 1 is configured to transport articles B (see, e.g., FIG. 2) between levels in a building with a plurality of levels including at least a lower level L and an upper level U. The article transport facility 1 includes a plurality of transport vehicles 2, a lower level rail 3 disposed in the lower level L, an upper level rail 4 disposed in the upper level U, an inter-level transport apparatus 5, and a control system 7. The article transport facility 1 further includes a processing apparatus 6 that performs a processing on the transport vehicles 2 (see, e.g., FIG. 3).

The transport vehicles 2 travel on the lower level rail 3 and the upper level rail 4. In the descriptions herein below, the direction in which each transport vehicle 2 travels along each of the lower level rail 3 and the upper level rail 4, is referred to as a “traveling direction F” (see, e.g., FIG. 3). Further, one side of the traveling direction F is referred to as a “first side of traveling direction F1,” and the other side of the traveling direction F, which is opposite to one side of the traveling direction F, is referred to as a “second side of traveling direction F2.”

In the present embodiment, the transport vehicle 2 travels toward the second side of traveling direction F2 on the lower level rail 3 and the upper level rail 4. Thus, in the present embodiment, the first side of traveling direction F1 is the rear side (upstream) of the traveling direction of the transport vehicle 2, and the second side of traveling direction F2 is the front side (downstream) of the traveling direction of the transport vehicle 2.

The transport vehicle 2 transports articles B in the building with the plurality of levels (the lower level L and the upper level U in the present example). The transport vehicle 2 travels on the lower level rail 3 disposed in the lower level L and the upper level rail 4 disposed in the upper level U. In the present embodiment, each of the lower level rail 3 and the upper level rail 4 is provided to form a traveling path R. In the present embodiment, the traveling path R includes a main transport path Rm formed in an annular shape, and a plurality of secondary transport paths Rs that are each formed in an annular shape, branch from the main transport path, and rejoin the main transport path Rm.

The articles B handled by the article transport facility 1 and transported by the transport vehicle 2 include various articles. For example, when the article transport facility 1 is used in a semiconductor manufacturing plant, the articles B are, for example, wafer storage containers that accommodate wafers (so-called FOUP: front opening unified pod), or reticle storage containers that accommodate reticles (so-called reticle pod). In this case, the transport vehicle 2 transports the articles B, such as the wafer storage containers or the reticle storage containers, along the traveling path R between processes.

In the present embodiment, unmanned transport vehicles, which travel in the vicinity of the ceiling 9 of each level, are used. As illustrated in FIG. 2, each transport vehicle 2 of the present embodiment includes a traveling unit 21 and a transfer unit 22. In the lower level L, the traveling unit 21 travels on a lower-level upper rail 3A or a lower-level lower rail 3B provided in the vicinity of the ceiling 9. The transfer unit 22 is supported by being suspended from the traveling unit 21, and holds an article B during the traveling of the traveling unit 21 and transfers the article B with respect to, for example, a supply unit of articles B or a processing apparatus.

In the present embodiment, the lower-level upper rail 3A is provided directly below the ceiling 9. The lower-level upper rail 3A is provided along the traveling path R. The lower-level upper rail 3A serves as a track on which the traveling unit 21 of the transport vehicle 2 travels, and is configured with a pair of rails separable in the left-right direction. The lower-level upper rail 3A is supported by a support frame in a state of being suspended directly from the ceiling 9.

The lower-level lower rail 3B is provided below the lower-level upper rail 3A in the vertical direction Z in the vicinity of the ceiling 9. The lower-level lower rail 3B is provided along only a portion of the traveling path R (the main transport path Rm in the present example). The lower-level lower rail 3B serves as a track on which the traveling unit 21 of the transport vehicle 2 travels, and is configured with a pair of rails separable in the left-right direction. The lower-level lower rail 3B is supported by a support frame in the state of being suspended from a support wall 9A provided along the horizontal plane further below the transfer unit 22 of the transport vehicle 2 traveling on the lower-level upper rail 3A.

Although not illustrated, the upper level rail 4 disposed on the upper level U has the same configuration. The upper level rail 4 includes an upper-level upper rail 4A and an upper-level lower rail 4B.

The upper-level upper rail 4A is provided directly below the ceiling of the upper level U. The upper-level upper rail 4A is provided along the traveling path R. The upper-level upper rail 4A serves as a track on which the traveling unit 21 of the transport vehicle 2 travels, and is configured with a pair of rails separable in the left-right direction. The upper-level upper rail 4A is supported by a support frame in the state of being suspended directly from the ceiling.

The upper-level lower rail 4B is provided below the upper-level upper rail 4A in the vertical direction Z in the vicinity of the ceiling of the upper level U. The upper-level lower rail 4B is provided along only a portion of the traveling path R (the main transport path Rm in the present example). The upper-level lower rail 4B serves as a track on which the traveling unit 21 of the transport vehicle 2 travels, and is configured with a pair of rails separable in the left-right direction. The upper-level lower rail 4B is supported by a support frame in the state of being suspended from a support wall provided along the horizontal plane further below the transfer unit 22 of the transport vehicle 2 traveling on the upper-level upper rail 4A.

The lower level rail 3 is disposed in the lower level L, which is one of the plurality of levels. As illustrated in FIG. 3, the lower level rail 3 includes a lower-level upper rail 3A and a lower-level lower rail 3B disposed below the lower-level upper rail 3A in the vertical direction Z. The lower-level upper rail 3A is provided on the entire traveling path R. The lower-level lower rail 3B is provided only in the vicinity of the inter-level transport apparatus 5.

The lower-level upper rail 3A includes a lower-level upstream upper rail portion 31 disposed on the first side of traveling direction F1 with respect to the inter-level transport apparatus 5, and a lower-level downstream upper rail portion 33 disposed on the second side of traveling direction F2 with respect to the inter-level transport apparatus 5. In the present embodiment, the upper-level upstream upper rail portion 31 corresponds to a “first rail portion,” and the upper-level downstream upper rail portion 33 corresponds to a “seventh rail portion.”

The lower-level lower rail 3B includes a lower-level upstream lower rail portion 32 disposed on the first side of traveling direction F1 with respect to the inter-level transport apparatus 5, and a lower-level downstream lower rail portion 34 disposed on the second side of traveling direction F2 with respect to the inter-level transport apparatus 5. In the present embodiment, the lower-level upstream lower rail portion 32 corresponds to a “second rail portion,” and the lower-level downstream lower rail portion 34 corresponds to an “eighth rail portion.”

The lower-level upstream lower rail portion 32 branches from the lower-level upstream upper rail portion 31, on the first side of traveling direction F1 with respect to the inter-level transport apparatus 5. In the present embodiment, the lower-level upstream lower rail portion 32 branches from the lower-level upstream upper rail portion 31, by a lower-level upstream elevation device 35 provided on the first side of traveling direction F1 with respect to the inter-level transport apparatus 5. The lower-level upstream elevation device 35 includes an elevation rail 36 and an elevation mechanism (elevator) (not illustrated) that moves the elevation rail 36 in the vertical direction Z over the lower-level upstream lower rail portion 32 and the lower-level upstream upper rail portion 31. Meanwhile, the elevation mechanism may be any one of various types such as a hydraulic drive mechanism and a motor drive mechanism (the same applies herein below).

The lower-level downstream lower rail portion 34 joins the lower-level downstream upper rail portion 33 on the second side of traveling direction F2 with respect to the inter-level transport apparatus 5. In the present embodiment, the lower-level downstream lower rail portion 34 joins the lower-level downstream upper rail portion 33 by a lower-level downstream elevation device 37 provided on the second side of traveling direction F2 with respect to the inter-level transport apparatus 5. The lower-level downstream elevation device 37 includes an elevation rail 38 and an elevation mechanism (not illustrated) that moves the elevation rail 38 in the vertical direction Z over the lower-level downstream lower rail portion 34 and the lower-level downstream upper rail portion 33.

In the present embodiment, wait sections W are set in the lower-level upstream lower rail portion 32 and the lower-level downstream lower rail portion 34 that make up the lower-level lower rail 3B. Each wait section W is a section where the transport vehicle 2 stops and waits, for example, until the transport vehicle 2 can be transported by the inter-level transport apparatus 5 or another transport vehicle 2 with transport priority passes. In the present embodiment, the wait sections W are also set in the lower-level upstream upper rail portion 31 and the lower-level downstream upper rail portion 33 that make up the lower-level upper rail 3A.

The upper level rail 4 is disposed in the upper level U, which is one of the plurality of levels and different from the lower level L. The upper level rail 4 is disposed in the upper level U provided at a higher level than the lower level L. As illustrated in FIG. 3, the upper level rail 4 includes the upper-level upper rail 4A and the upper-level lower rail 4B disposed below the upper-level upper rail 4A in the vertical direction Z. The upper-level upper rail 4A is provided on the entire traveling path R. The upper-level lower rail 4B is provided only in the vicinity of the inter-level transport apparatus 5.

The upper-level upper rail 4A includes an upper-level upstream upper rail portion 41 disposed on the first side of traveling direction F1 with respect to the inter-level transport apparatus 5, and an upper-level downstream upper rail portion 43 disposed on the second side of traveling direction F2 with respect to the inter-level transport apparatus 5. In the present embodiment, the upper-level upstream upper rail portion 41 corresponds to a “fifth rail portion,” and the upper-level downstream upper rail portion 43 corresponds to a “third rail portion.”

The upper-level lower rail 4B includes an upper-level upstream lower rail portion 42 disposed on the first side of traveling direction F1 with respect to the inter-level transport apparatus 5, and an upper-level downstream lower rail portion 44 disposed on the second side of traveling direction F2 with respect to the inter-level transport apparatus 5. In the present embodiment, the upper-level upstream lower rail portion 42 corresponds to a “sixth rail portion,” and the upper-level downstream lower rail portion 44 corresponds to a “fourth rail portion.”

The upper-level upstream lower rail portion 42 branches from the upper-level upstream upper rail portion 41 on the first side of traveling direction F1 with respect to the inter-level transport apparatus 5. In the present embodiment, the upper-level upstream lower rail portion 42 branches from the upper-level upstream upper rail portion 41, by an upper-level upstream elevation device 45 provided on the first side of traveling direction F1 with respect to the inter-level transport apparatus 5. The upper-level upstream elevation device 45 includes an elevation rail 46 and an elevation mechanism (not illustrated) that moves the elevation rail 46 in the vertical direction Z over the upper-level upstream lower rail portion 42 and the upper-level upstream upper rail portion 41.

The upper-level downstream lower rail portion 44 joins the upper-level downstream upper rail portion 43 on the second side of traveling direction F2 with respect to the inter-level transport apparatus 5. In the present embodiment, the upper-level downstream lower rail portion 44 joins the upper-level downstream upper rail portion 43 by an upper-level downstream elevation device 47 provided on the second side of traveling direction F2 with respect to the inter-level transport apparatus 5. The upper-level downstream elevation device 47 includes an elevation rail 48, and an elevation mechanism (not illustrated) that moves the elevation rail 48 in the vertical direction Z over the upper-level downstream lower rail portion 44 and the upper-level downstream upper rail portion 43.

In the present embodiment, wait sections W are set in the upper-level upstream lower rail portion 42 and the upper-level downstream lower rail portion 44 that make up the upper-level lower rail 4B. In the present embodiment, the wait sections W are also set in the upper-level upstream upper rail portion 41 and the upper-level downstream upper rail portion 43 that make up the upper-level upper rail 4A.

As illustrated in FIG. 1, the inter-level transport apparatus 5 is provided over the lower level L and the upper level U. The inter-level transport apparatus 5 transports the transport vehicle 2 in the vertical direction Z over the lower level L and the upper level U. As illustrated in FIG. 3, the inter-level transport apparatus 5 includes an upper elevation rail 51 on which the transport vehicle 2 travels, a lower elevation rail 52 on which the transport vehicle 2 travels, and an elevation mechanism (not illustrated) that moves the upper elevation rail 51 and the lower elevation rail 52 in the vertical direction Z.

The upper elevation rail 51 and the lower elevation rail 52 are provided in parallel. In the present embodiment, the upper elevation rail 51 and the lower elevation rail 52 are arranged side by side in the vertical direction Z. The upper elevation rail 51 and the lower elevation rail 52 are arranged to at least partially overlap with each other when viewed from the vertical direction. In the present embodiment, the upper elevation rail 51 and the lower elevation rail 52 are arranged side by side along the vertical direction Z in the same range of the traveling direction F, and entirely overlap with each other when viewed from the vertical direction. In the present embodiment, each of the upper elevation rail 51 and the lower elevation rail 52 is set to have a length that allows the entry of a single transport vehicle 2.

The elevation mechanism moves the upper elevation rail 51 and the lower elevation rail 52 in the vertical direction Z while maintaining the positional relationship of the rails. The elevation mechanism moves the upper elevation rail 51 and the lower elevation rail 52 together at the same time. The distance in the vertical direction Z between the upper elevation rail 51 and the lower elevation rail 52 is equal to the distance in the vertical direction Z between the lower-level upper rail 3A and the lower-level lower rail 3B, and is also equal to the distance in the vertical direction Z between the upper-level upper rail 4A and the upper-level lower rail 4B.

As illustrated in FIG. 3, the elevation mechanism is configured to stop the upper elevation rail 51 and the lower elevation rail 52 at a predetermined lower-level stop position P1 in the lower level L and a predetermined upper-level stop position P2 in the upper level U. The lower-level stop position P1 and the upper-level stop position P2 are representative positions for the upper elevation rail 51 and the lower elevation rail 52. Meanwhile, the elevation mechanism may be any one of various types such as a hydraulic drive mechanism and a motor drive mechanism.

In the state where the upper elevation rail 51 and the lower elevation rail 52 stop at the lower-level stop position P1, the upper elevation rail 51 is connected to the lower-level upstream upper rail portion 31 from the second side of traveling direction F2, and connected to the lower-level downstream upper rail portion 33 from the first side of traveling direction F1. Further, the lower elevation rail 52 is connected to the lower-level upstream lower rail portion 32 from the second side of traveling direction F2, and is connected to the lower-level downstream lower rail portion 34 from the first side of traveling direction F1.

In the state where the upper elevation rail 51 and the lower elevation rail 52 stop at the upper-level stop position P2, the upper elevation rail 51 is connected to the upper-level upstream upper rail portion 41 from the second side of traveling direction F2, and is connected to the upper-level downstream upper rail portion 43 from the first side of traveling direction F1. Further, the lower elevation rail 52 is connected to the upper-level upstream lower rail portion 42 from the second side of traveling direction F2, and is connected to the upper-level downstream lower rail portion 44 from the first side of traveling direction F1.

In the present embodiment, the lower-level stop position P1 corresponds to a “first stop position,” and the upper-level stop position P2 corresponds to a “second stop position.”

In the present embodiment, processing apparatuses 6 are disposed in the wait sections W of the lower-level upstream lower rail portion 32, the lower-level downstream lower rail portion 34, the upper-level upstream lower rail portion 42, and the upper-level downstream lower rail portion 44, to perform a processing on the transport vehicles 2 stopping in the wait sections W. The processing apparatuses 6 are not disposed in the wait sections W of the lower-level upstream upper rail portion 31, the lower-level downstream upper rail portion 33, the upper-level upstream upper rail portion 41, and the upper-level downstream upper rail portion 43. Each processing apparatus 6 may be, for example, an apparatus that performs a predetermined inspection or cleaning on the transport vehicle 2. Alternatively, when the transport vehicle 2 is equipped with a battery for traveling, the processing apparatus 6 may be an apparatus that charges the battery. When the plurality of processing apparatuses 6 are provided, the processing apparatuses 6 may perform the same type of processing, or at least one of the processing apparatuses 6 may perform a different type of processing from the others.

The control system 7 controls the plurality of transport vehicles 2. Further, the control system 7 controls the inter-layer transport apparatus 5, the lower-level upstream elevation device 35, the lower-level downstream elevation device 37, the upper-level upstream elevation device 45, and the upper-level downstream elevation device 47. The control system 7 includes an arithmetic processing device such as a central processing unit (CPU), and a main storage device such as a random access memory (RAM) or a read only memory (ROM). Each function of the control system 7 is implemented by the cooperation of the arithmetic processing device and a program executed on the arithmetic processing device.

The control system 7 may be configured with a single hardware component, or a set of multiple hardware components (multiple separate hardware components) that may communicate with each other by wire or wirelessly. For example, the control system 7 may be configured with a host control device provided in a control facility (not illustrated), and a control terminal device that is equipped in each transport vehicle 2 and may communicate with the host control device.

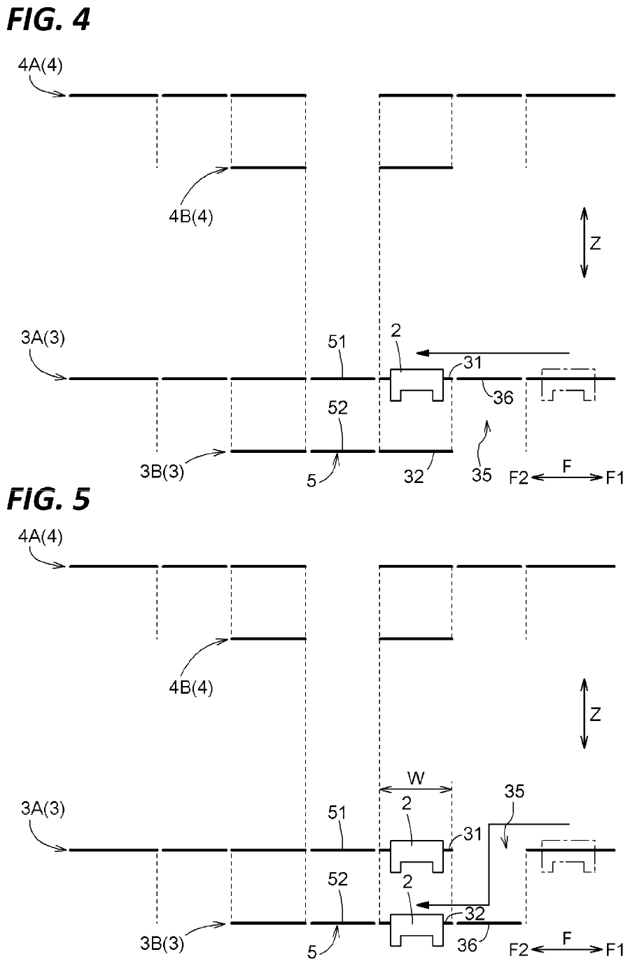

Hereinafter, an example of an article transport by the transport vehicle 2 is described with reference to FIGS. 1 to 11. As illustrated in FIG. 4, in the lower level L, a transport vehicle 2 that is traveling toward the lower-level upstream upper rail portion 31 passes the elevation rail 36 of the lower-level upstream elevation device 35 present at a raised position, and arrives at the downstream end of the lower-level upstream upper rail portion 31. The transport vehicle 2 waits in the wait section W set in the lower-level upstream upper rail portion 31.

As illustrated in FIG. 5, in the lower level L, a subsequent transport vehicle 2 that is traveling toward the lower-level upstream upper rail portion 31 moves from the raised position to a lowered position by the lower-level upstream elevation device 35, and then, arrives at the downstream end of the lower-level upstream lower rail portion 32. The transport vehicle 2 waits in the wait section W set in the lower-level upstream lower rail portion 32. During the waiting, a processing may be performed on the transport vehicle 2 by the processing apparatus 6.

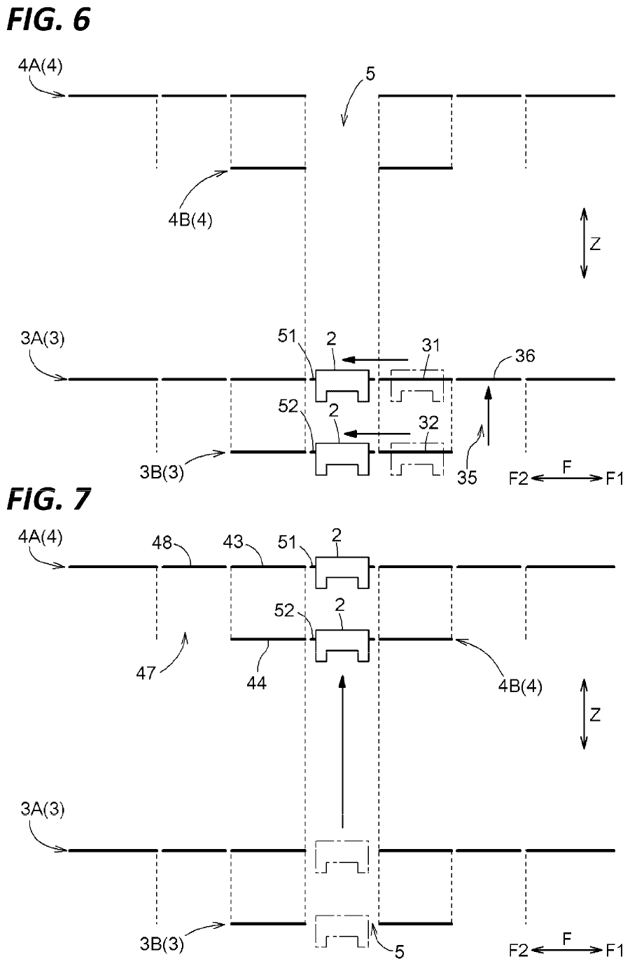

As illustrated in FIG. 6, the two transport vehicles 2 enter the upper elevation rail 51 and the lower elevation rail 52 of the inter-level transport apparatus 5 present at the lower-level stop position P1, respectively. The transport vehicle 2 that is waiting in the wait section W of the lower-level upstream upper rail portion 31 enters the upper elevation rail 51, and the transport vehicle 2 that is waiting in the wait section W of the lower-level upstream lower rail portion 32 enters the lower elevation rail 52.

As illustrated in FIG. 7, the two transport vehicles 2 are moved from the lower-level stop position P1 to the upper-level stop position P2 by the inter-level transport apparatus 5.

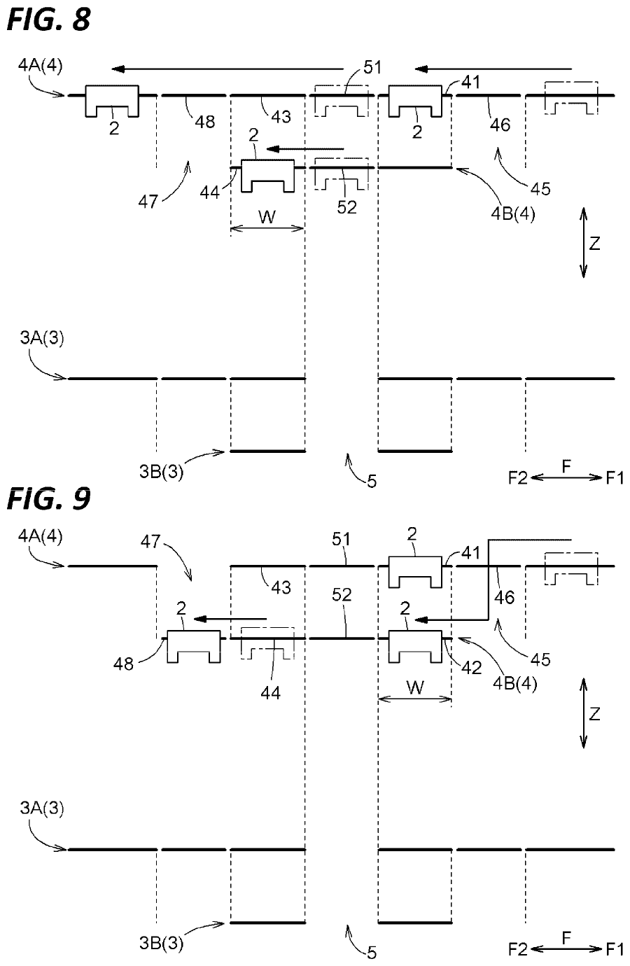

As illustrated in FIG. 8, the transport vehicle 2 that has been transported from the lower elevation rail 52 of the inter-level transport apparatus 5 enters the upper-level downstream lower rail portion 44. Then, the transport vehicle 2 waits in the wait section W set in the upper-level downstream lower rail portion 44. During the waiting, a processing may be performed on the transport vehicle 2 by the processing apparatus 6. Meanwhile, the transport vehicle 2 that has been transported from the upper elevation rail 51 of the inter-level transport apparatus 5 enters the upper-level downstream upper rail portion 43, passes the elevation rail 48 of the upper-level downstream elevation device 47 present at the raised position, and further travels toward its destination.

In this way, the control system 7 allows the transport vehicle 2 that is traveling on the upper-level downstream upper rail portion 43, to travel with priority at the confluence where the upper-level downstream lower rail portion 44 joins the upper-level downstream upper rail portion 43 (priority travel process).

In the example of FIG. 8, in the upper level U, another transport vehicle 2 is traveling toward the upper-level upstream upper rail portion 41. The transport vehicle 2 that is traveling toward the upper-level upstream upper rail portion 41 passes the elevation rail 46 of the upper-level upstream elevation device 45 present at the raised position, and arrives at the downstream end of the upper-level upstream upper rail portion 41. The transport vehicle 2 waits in the wait section W set in the upper-level upstream upper rail portion 41.

As illustrated in FIG. 9, the transport vehicle 2 that is waiting in the wait section W of the upper-level downstream lower rail portion 44 enters the elevation rail 48 of the upper-level downstream elevation device 47 that has been lowered to the lowered position after another transport vehicle 2 passes the elevation rail 48 as described above. Further, in the upper level U, a subsequent transport vehicle 2 that is traveling toward the upper-level upstream upper rail portion 41 is moved from the raised position to the lowered position by the upper-level upstream elevation device 45, and then, arrives at the downstream end of the upper-level upstream lower rail portion 42. The transport vehicle 2 waits in the wait section W set in the upper-level upstream lower rail portion 42. During the waiting, a processing may be performed on the transport vehicle 2 by the processing apparatus 6.

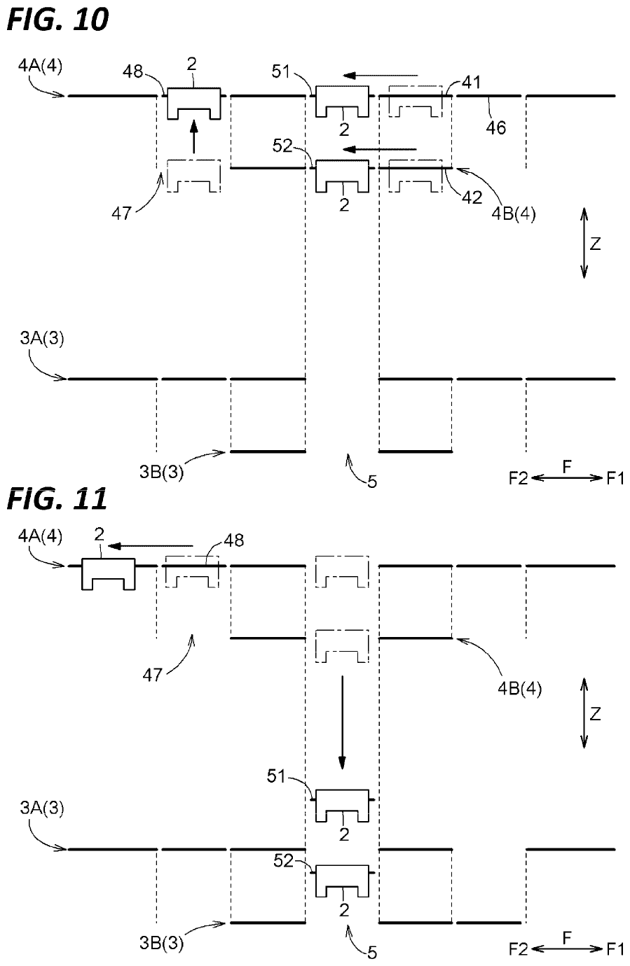

As illustrated in FIG. 10, the two transport vehicles 2 enter the upper elevation rail 51 and the lower elevation rail 52 of the inter-level transport apparatus 5 present at the upper-level stop position P2, respectively. The transport vehicle 2 that is waiting in the wait section W of the upper-level upstream upper rail portion 41 enters the upper elevation rail 51, and the transport vehicle 2 that is waiting in the wait section W of the upper-level upstream lower rail portion 42 enters the lower elevation rail 52. In the meantime, the transport vehicle 2 of the elevation rail 48 is moved from the lowered position to the raised position by the upper-level downstream elevation device 47.

As illustrated in FIG. 11, the two transport vehicles 2 are moved from the upper-level stop position P2 to the lower-level stop position P1 by the inter-level transport apparatus 5. Further, the transport vehicle 2 moved to the raised position by the upper-level downstream elevation device 47 enters the upper-level downstream upper rail portion 43 and travels toward its destination.

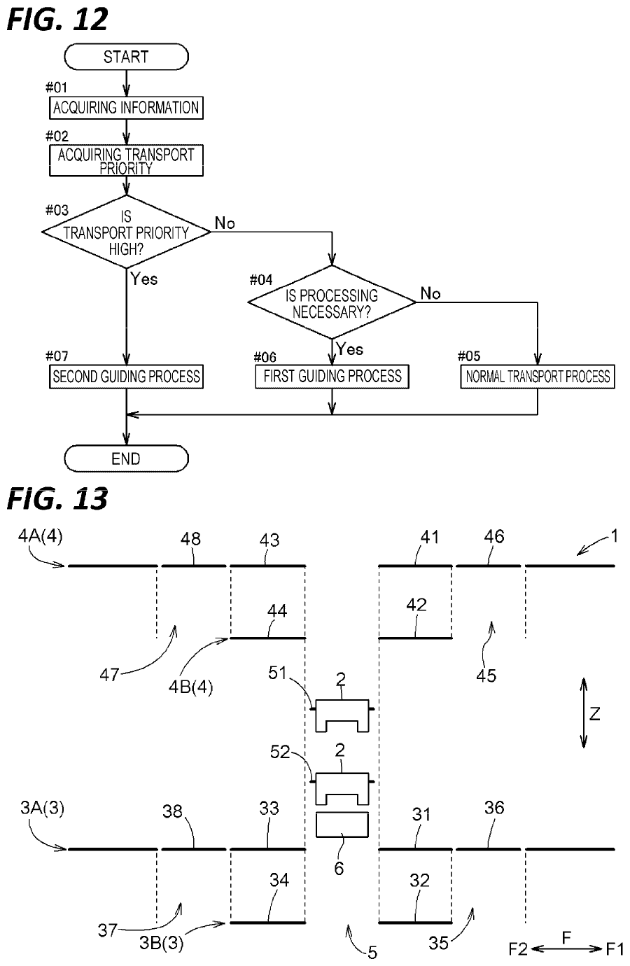

While the descriptions have been made on the basic operation of the article transport by the transport vehicles 2 in the vicinity of the inter-level transport apparatus 5, the control system 7 of the present embodiment is configured to also perform a special operation. The operation is described below with reference to the flowchart of FIG. 12. First, the control system 7 performs an information acquisition process and a transport priority acquisition process for each of the plurality of transport vehicles 2 (steps #01 and #02). Here, the information acquisition process acquires information necessary to determine whether a processing by the processing apparatus 6 is necessary. For example, when the processing apparatus 6 performs an inspection or cleaning on the transport vehicle 2, information about, for example, the number of days elapsed from the previous processing is acquired. When the processing apparatus 6 performs battery charging, information about, for example, the remaining battery level is acquired by a sensor.

The transport priority acquisition process acquires a transport priority of an article that is being transported. In the present embodiment, the transport priority of the article B that is being transported is obtained by acquiring information on a priority of a transport request from a host system that controls the entire article transport facility 1.

Based on the result of the transport priority acquisition process, the control system 7 determines whether transfer priority is high (step #03). In the present embodiment, the determination process corresponds to a “transport priority determination process.” In the present embodiment, the transport priority of the article B that is being transported is managed as a numerical value, and it is determined whether the numerical value of the transport priority is equal to or more than a predetermined determination threshold value.

When it is determined that the transfer priority is less than the determination threshold value, i.e., the transport priority is not high (step #03: No), it is then determined whether a processing by the processing apparatus 6 is necessary, based on the result of a necessity determination process (step #04). In the present embodiment, this determination process corresponds to the “necessity determination process.”

When it is determined that a processing by the processing unit 6 is unnecessary (step #04: No), a normal transport process is performed (step #05). In the normal transport process, the processing apparatus 6 is not operated, and the transport process is performed based on the basic operation described with reference to FIGS. 4 to 11.

Meanwhile, when it is determined as a result of the necessity determination process that a processing by the processing apparatus 6 is necessary (step #04: Yes), the control system 7 performs a first guiding process to guide the transport vehicle 2 to the wait section W where the processing apparatus 6 is disposed (step #06). For example, in the example of FIG. 4, when a processing is necessary for the transport vehicle 2, which is the first traveling vehicle, the transport vehicle 2 is guided to the wait section W of the lower-level upstream lower rail portion 32 where the processing apparatus 6 is disposed, instead of the wait section W of the lower-level upstream upper rail portion 31 where no processing apparatus 6 is disposed. By performing the first guiding process, the processing necessary for the transport vehicle 2 may be appropriately performed also using the waiting time.

Further, for the transport vehicle 2, of which transport priority is determined to be equal to or more than the determination threshold value, i.e., transport priority is determined to be high as a result of the transport priority determination process, the control system 7 performs a second guiding process to guide the transport vehicle 2 to the upper-level elevation rail 51, regardless of the result of the necessity determination process (step #07). For example, in the example described above, when the transport priority of an article B that is being transported is high, the the transport vehicle 2 is guided to the wait section W of the lower-level upstream upper rail portion 31 to be connected to the upper elevation rail 51, instead of the wait section W of the lower-level upstream lower rail portion 32 where the processing apparatus 6 is disposed. By performing the second guiding process, the transport vehicle 2 may travel with priority after moving to another level by the inter-level transport apparatus 5, so that the article B may be delivered earlier to its destination.

### OTHER EMBODIMENTS

(1) In the embodiment above, descriptions are made on an example of the configuration, in which the transport priority has precedence over the necessity of a processing when the article transport is performed by the transport vehicle 2 in the vicinity of the inter-level transport apparatus 5. However, without being limited to the configuration, for example, the necessity of a processing and the transport priority may be comprehensively considered to perform the article transport by the transport vehicle 2 in the vicinity of the inter-level transport apparatus 5.

(2) In the embodiment above, descriptions are made on an example of the configuration, in which the processing apparatuses 6 are disposed in the wait sections W of the lower-level upstream lower rail portion 32, the lower-level downstream lower rail portion 34, the upper-level upstream lower rail portion 42, and the upper-level downstream lower rail portion 44. However, without being limited to the configuration, for example, the processing apparatuses 6 may be disposed in the wait sections W of only some of the lower-level upstream lower rail portion 32, the lower-level downstream lower rail portion 34, the upper-level upstream lower rail portion 42, and the upper-level downstream lower rail portion 44. Further, the processing apparatus 6 may also be disposed in at least one of the wait sections W of the lower-level upstream upper rail portion 31, the lower-level downstream upper rail portion 33, the upper-level upstream upper rail portion 41, and the upper-level downstream upper rail portion 43.

(3) In the embodiment above, descriptions are made on an example of the configuration, in which the processing apparatuses 6 are disposed in a fixed form in the wait sections W of the lower-level upstream lower rail portion 32, the lower-level downstream lower rail portion 34, the upper-level upstream lower rail portion 42, and the upper-level downstream lower rail portion 44. However, without being limited to the configuration, for example, the processing apparatus 6 may be movably disposed in the inter-level transport apparatus 5 as illustrated in FIG. 13. In this case, the processing apparatus 6 may be configured to move in the vertical direction Z together with the upper elevation rail 51 and the lower elevation rail 52 by the elevation mechanism of the inter-level transport apparatus 5.

(4) In the embodiment above, descriptions are made on an example of the configuration, in which the lower-level lower rail 3B and the upper-level lower rail 4B are provided only in the vicinity of the inter-level transport apparatus 5. However, without being limited to the configuration, for example, at least one of the lower-level lower rail 3B and the upper-level lower rail 4B may be provided over a relatively wide area including the vicinity of the inter-level transport apparatus 5.

(5) In the embodiment above, descriptions are made on an example of the configuration, in which the lower-level upstream upper rail portion 31 and the lower-level upstream lower rail portion 32 are branched by the lower-level upstream elevation device 35. However, without being limited to the configuration, for example, the lower-level upstream upper rail portion 31 and the lower-level upstream lower rail portion 32 may be branched by a branch rail. The branch rail may branch the lower-level upstream upper rail portion 31 and the lower-level upstream lower rail portion 32 in the vertical direction Z or in the horizontal direction. The same applies to the branch of the upper-level upstream upper rail portion 41 and the upper-level upstream lower rail portion 42.

(6) In the embodiment above, descriptions are made on an example of the configuration, in which the lower-level downstream upper rail portion 33 and the lower-level downstream lower rail portion 34 join by the lower-level downstream elevation device 37. However, without being limited to the configuration, for example, the lower-level downstream upper rail portion 33 and the lower-level downstream lower rail portion 34 may join by a joining rail. The lower-level downstream upper rail portion 33 and the lower-level downstream lower rail portion 34 may join by the joining rail in the vertical direction Z or in the horizontal direction. The same applies to the confluence of the upper-level downstream upper rail portion 43 and the upper-level downstream lower rail portion 44.

(7) In the embodiment above, descriptions are made on an example of the configuration, in which the upper elevation rail 51 and the lower elevation rail 52 of the inter-level transport apparatus 5 entirely overlap with each other in the vertical direction. However, without being limited to the configuration, for example, the upper elevation rail 51 and the lower elevation rail 52 may have different lengths to partially overlap with each other when viewed from the vertical direction. Further, for example, the upper elevation rail 51 and the lower elevation rail 52 may be arranged side by side horizontally so as not to overlap with each other in the vertical direction.

(8) In the embodiment above, descriptions are made on an example of the configuration, in which the upper elevation rail 51 and the lower elevation rail 52 of the inter-level transport apparatus 5 transport the transport vehicles 2 one by one. However, without being limited to the configuration, for example, at least one of the upper elevation rail 51 and the lower elevation rail 52 may collectively transport a plurality of transport vehicles 2.

(9) In the embodiment above, descriptions are made on an example of the configuration, in which the traveling directions of the transport vehicles 2 on the lower level rail 3 and the upper level rail 4 are forward parallel. However, without being limited to the configuration, and the traveling directions of the transport vehicles 2 on the lower level rail 3 and the upper level rail 4 may be reversely parallel. In this case, the “traveling direction F” may be determined based on, for example, the traveling direction of the transport vehicle 2 traveling on the lower level rail 3. Further, in the upper level U, in the state where the upper elevation rail 51 and the lower elevation rail 52 stop at the upper-level stop position P2, the upper elevation rail 51 is connected to the upper-level upstream upper rail portion 41 from the first side of traveling direction F1, and connected to the upper-level downstream upper rail portion 43 from the second side of traveling direction F2. The lower elevation rail 52 is connected to the upper-level upstream lower rail portion 42 from the first side of traveling direction F1, and connected to the upper-level downstream lower rail portion 44 from the second side of traveling direction F2.

(10) In the embodiment above, descriptions are made primarily assuming the configuration, in which the transport vehicle 2 travels in only one direction. However, without being limited to the configuration, for example, the transport vehicle 2 may travel in both directions.

(11) In the embodiment above, descriptions are made on an example of the configuration, in which the lower level rail 3 and the upper level rail 4 are supported by being suspended from the ceiling 9 or the support wall 9A. However, without being limited to the configuration, for example, the lower level rail 3 and the upper level rail 4 may be provided on the floor.

(12) In the embodiment above, descriptions are made on an example of the configuration, in which the article transport facility 1 is provided in a two-story building having the lower level L and the upper level U. However, without being limited to the configuration, the article transport facility 1 of the present embodiment may be applied identically to a building with three or more levels including the lower level L, intermediate levels (a first intermediate level, a second intermediate level, . . . ), and the upper level U.

### Summary of Embodiments

In summary, the article transfer facility according to the present disclosure includes the following configuration.

An article transport facility includes: a plurality of transport vehicles that transport articles inside a building with a plurality of levels; a first level rail disposed in a first level, which is one of the plurality of levels, and allowing the plurality of transport vehicles to travel thereon; a second level rail disposed in a second level, which is one of the plurality of levels and different from the first level, and allowing the plurality of transport vehicles thereon; and an inter-level transport apparatus that transports the plurality of transport vehicles in a vertical direction over the first level and the second level. The inter-level transport apparatus includes a first elevation rail, on which the plurality of transport vehicles travel, a second elevation rail, on which the plurality of transport vehicles travel, the second elevation rail being provided in parallel with the first elevation rail, and an elevation mechanism configured to move the first elevation rail and the second elevation rail in the vertical direction while maintaining a positional relationship between the first elevation rail and the second elevation rail, the elevation mechanism stops the first elevation rail and the second elevation rail at a predetermined first stop position in the first level and a predetermined second stop position in the second level, a direction along each of the first level rail and the second level rail is a traveling direction, one side of the traveling direction is a first side of the traveling direction, and an opposite side of the traveling direction is a second side of the traveling direction, the first level rail includes a first rail portion that is connected to the first elevation rail present at the first stop position from the first side of the traveling direction, and a second rail portion that is connected to the second elevation rail present at the first stop position from the first side of the traveling direction, and the second level rail includes a third rail portion that is connected to the first elevation rail present at the second stop position from the first or second side of the traveling direction, and a fourth rail portion that is connected to the second elevation rail present at the second stop position from the first or second side of the traveling direction.

According to this configuration, two or more transport vehicles may be simultaneously transported from one level to another level. Thus, as compared to the configuration in which the transport vehicles are transported one by one between levels, the efficiency in transporting the transport vehicles between the levels may be improved. Therefore, it is possible to provide an article transport facility with the improved efficiency in transporting articles among a plurality of levels.

In an aspect, the first elevation rail and the second elevation rail may be arranged side by side in the vertical direction.

According to this configuration, since the first elevation rail and the second elevation rail are arranged vertically, the installation area of the inter-level transport apparatus may be reduced, as compared to a configuration in which the rails are arranged horizontally. Therefore, the overall size of the article transport facility may be minimized.

In an aspect, the plurality of transport vehicles may travel on the first level rail toward the second side of the traveling direction, the second rail portion may branch from the first rail portion on the first side of the traveling direction with respect to the inter-level transport apparatus, and a wait section may be set in the second rail portion to allow each of the plurality of transport vehicles to stop and wait therein.

According to this configuration, since the second rail portion is configured to branch from the first rail portion, the installation range of the second rail portion may be reduced. Therefore, the first level rail may be simplified. Further, since the wait section is set in the second rail portion branching from the first rail portion, it is possible to appropriately secure the space where a transport vehicle is waiting by the inter-level transport apparatus without interfering with the passage of another transport vehicle traveling on the first rail portion.

In an aspect, the third rail portion may be connected to the first elevation rail present at the second stop position from the second side of the traveling direction, and the fourth rail portion may be connected to the second elevation rail present at the second stop position from the second side of the traveling direction, the second level rail may include a fifth rail portion that is connected to the first elevation rail present at the second stop position from the first side of the traveling direction, and a sixth rail portion that is connected to the second elevation rail present at the second stop position from the first side of the traveling direction, the fourth rail portion may join the third rail portion on the second side of the traveling direction with respect to the inter-level transport apparatus, and the wait section may also be set in the fourth rail portion.

According to this configuration, since the traveling directions of the transport vehicles on the first level rail and the second level rail are the same, the transport efficiency in the entire facility may be improved. Further, since the fourth rail portion is configured to join the third rail portion, the installation range of the fourth rail portion may be reduced. Therefore, the second level rail may be simplified. Further, since the wait section is set in the fourth rail portion that joins the third rail portion, it is possible to appropriately secure the space where a transport vehicle waiting until another transport vehicle passes at the confluence of the fourth rail portion and the third rail portion may wait without interfering with the passage of the transport vehicle traveling on the third rail portion (e.g., the transport vehicle that has entered the third rail portion from the fifth rail portion).

In an aspect, a processing apparatus may be disposed corresponding to the wait section to perform a processing on each of the plurality of transport vehicles that stops in the wait section.

According to this configuration, a processing (e.g., inspections or cleaning) may be performed on the transport vehicle, using the time during which the transport vehicle is waiting in the wait section. Therefore, the processing on the transport vehicle may be efficiently performed, while suppressing the deterioration of the efficiency in transporting articles by transport vehicles.

In an aspect, the article transport facility may include a control system that controls the plurality of transport vehicles, the control system may perform a priority travel process to allow a transport vehicle traveling on the third rail portion to travel with priority over a transport vehicle traveling on the fourth rail portion, at a confluence where the fourth rail portion joins the third rail portion.

According to this configuration, at the confluence of the fourth rail portion and the third rail portion, the transport vehicle traveling on the third rail portion has priority, and the transport vehicle waiting for passage on the fourth rail portion may appropriately wait in the wait section set in the fourth rail portion.

In an aspect, the article transport facility may include a control system that controls the plurality of transport vehicles. The control system may perform a necessity determination process to determine whether the processing by the processing apparatus is necessary for each of the plurality of transport vehicles, and a first guiding process to guide a transport vehicle, for which the processing by the processing apparatus is determined to be necessary as a result of the necessity determination process, to the wait section where the processing apparatus is disposed.

According to this configuration, through the first guiding process, the transport vehicle requiring the processing is guided to the wait section where the processing apparatus is disposed, so that the processing necessary for the transport vehicle may be appropriately performed as needed.

In an aspect, for each of the plurality of transport vehicles, the control system may perform a transport priority determination process to determine a transport priority of an article that is being transported, and may perform a second guiding process to guide a transport vehicle, for which the transport priority is determined to be equal to or more than a predetermined determination threshold value as a result of the transport priority determination process, to the first elevation rail, regardless of the result of the necessity determination process.

According to this configuration, through the second guiding process, the transport vehicle with high priority for the article transport may be guided to the rail portion where the processing apparatus is not disposed, instead of the wait section or the rail portion where the processing apparatus is disposed. Therefore, transport vehicles may quickly pass the inter-level transport apparatus and the surroundings thereof, so that articles may be delivered to destinations at early times.

In an aspect, a processing apparatus that performs a processing on a transport vehicle present on at least one of the first elevation rail and the second elevation rail may be configured to move in a vertical direction together with the first elevation rail and the second elevation rail.

According to this configuration, a processing (e.g., inspection or cleaning) may be performed on the transfer vehicle, using the time during which the transport vehicle is moved in the vertical direction by the elevation mechanism. Therefore, the processing on the transport vehicle may be efficiently performed, while suppressing the deterioration of the efficiency in transporting articles by transport vehicles.

The article transport facility according to the present disclosure may achieve at least one of the effects described above.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An article transport facility comprising:
a plurality of transport vehicles configured to transport articles inside a building with a plurality of levels;
a first level rail disposed in a first level, which is one of the plurality of levels, and configured to allow the plurality of transport vehicles to travel thereon;
a second level rail disposed in a second level, which is one of the plurality of levels and different from the first level, and configured to allow the plurality of transport vehicles to travel thereon; and
an inter-level transport apparatus configured to transport the plurality of transport vehicles in a vertical direction over the first level and the second level,
wherein the inter-level transport apparatus includes a first elevation rail on which the plurality of transport vehicles travel, a second elevation rail on which the plurality of transport vehicles travel, the second elevation rail being provided in parallel with the first elevation rail, and an elevator configured to move the first elevation rail and the second elevation rail in the vertical direction while maintaining a positional relationship between the first elevation rail and the second elevation rail,
the elevator is configured to stop the first elevation rail and the second elevation rail at a predetermined first stop position in the first level and a predetermined second stop position in the second level,
a direction along each of the first level rail and the second level rail is a traveling direction, one side of the traveling direction is a first side of the traveling direction, and an opposite side of the traveling direction is a second side of the traveling direction,
the first level rail includes a first rail portion that is connected to the first elevation rail present at the first stop position from the first side of the traveling direction, and a second rail portion that is connected to the second elevation rail present at the first stop position from the first side of the traveling direction, and
the second level rail includes a third rail portion that is connected to the first elevation rail present at the second stop position from the first or second side of the traveling direction, and a fourth rail portion that is connected to the second elevation rail present at the second stop position from the first or second side of the traveling direction.

2. The article transport facility according to claim 1, wherein the first elevation rail and the second elevation rail are arranged side by side in the vertical direction.

3. The article transport facility according to claim 1, wherein the plurality of transport vehicles travel on the first level rail toward the second side of the traveling direction,
the second rail portion branches from the first rail portion on the first side of the traveling direction with respect to the inter-level transport apparatus, and
a wait section is set in the second rail portion to allow each of the plurality of transport vehicles to stop and wait therein.

4. The article transport facility according to claim 3, wherein the third rail portion is connected to the first elevation rail present at the second stop position from the second side of the traveling direction, and the fourth rail portion is connected to the second elevation rail present at the second stop position from the second side of the traveling direction,
the second level rail includes a fifth rail portion that is connected to the first elevation rail present at the second stop position from the first side of the traveling direction, and a sixth rail portion that is connected to the second elevation rail present at the second stop position from the first side of the traveling direction,
the fourth rail portion joins the third rail portion on the second side of the traveling direction with respect to the inter-level transport apparatus, and
the wait section is also set in the fourth rail portion.

5. The article transport facility according to claim 3, wherein a processing apparatus is disposed corresponding to the wait section to perform a processing on each of the plurality of transport vehicles that stops in the wait section.

6. The article transport facility according to claim 4, further comprising:
a control system configured to control the plurality of transport vehicles,
wherein the control system performs a priority travel process to allow a transport vehicle traveling on the third rail portion to travel with priority over a transport vehicle traveling on the fourth rail portion, at a confluence where the fourth rail portion joins the third rail portion.

7. The article transport facility according to claim 5, further comprising:
a control system configured to control the plurality of transport vehicles,
wherein the control system performs
a necessity determination process to determine whether the processing by the processing apparatus is necessary for each of the plurality of transport vehicles, and
a first guiding process to guide a transport vehicle, for which the processing by the processing apparatus is determined to be necessary as a result of the necessity determination process, to the wait section where the processing apparatus is disposed.

8. The article transport facility according to claim 7, wherein for each of the plurality of transport vehicles, the control system performs a transport priority determination process to determine a transport priority of an article that is being transported, and performs a second guiding process to guide a transport vehicle, for which the transport priority is determined to be equal to or more than a predetermined determination threshold value as a result of the transport priority determination process, to the first elevation rail, regardless of the result of the necessity determination process.

9. The article transport facility according to claim 1, wherein a processing apparatus is configured to move in a vertical direction together with the first elevation rail and the second elevation rail, thereby performing a processing on a transport vehicle present on at least one of the first elevation rail and the second elevation rail.
